(19) United States
(12) Patent Application Publication
(10) Pub. No.: US 2013/0089962 A1
(43) Pub. Date: Apr. 11, 2013

(54) SEMICONDUCTOR PROCESS

(71) Applicants: Chung-Fu Chang, Kaohsiung City (TW); Shin-Chuan Huang, Tainan City (TW); Yu-Hsiang Hung, Tainan City (TW); Chia-Jong Liu, Ping-Tung County (TW); Pei-Yu Chou, Tainan City (TW); Jyh-Shyang Jenq, Tainan City (TW); Ling-Chun Chou, Yun-Lin County (TW); I-Chang Wang, Tainan City (TW); Ching-Wen Hung, Tainan City (TW); Ted Ming-Lang Guo, Tainan City (TW); Chun-Yuan Wu, Yun-Lin County (TW)

(72) Inventors: Chung-Fu Chang, Kaohsiung City (TW); Shin-Chuan Huang, Tainan City (TW); Yu-Hsiang Hung, Tainan City (TW); Chia-Jong Liu, Ping-Tung County (TW); Pei-Yu Chou, Tainan City (TW); Jyh-Shyang Jenq, Tainan City (TW); Ling-Chun Chou, Yun-Lin County (TW); I-Chang Wang, Tainan City (TW); Ching-Wen Hung, Tainan City (TW); Ted Ming-Lang Guo, Tainan City (TW); Chun-Yuan Wu, Yun-Lin County (TW)

(21) Appl. No.: 13/270,240

(22) Filed: Oct. 11, 2011

(51) Int. Cl. H01L 21/336

(52) U.S. Cl. 438/299; 257/E21.409

(57) ABSTRACT

A semiconductor process includes the following steps. A substrate is provided. A gate structure is formed on the substrate. A spacer is formed on the substrate beside the gate structure. The spacer includes a first spacer and a second spacer located on the external surface of the first spacer. A first etching process is performed to etch and form at least a recess in the substrate beside the spacer and entirely remove the second spacer. The etching rate of the first etching process to the first spacer is lower than the etching rate of the first etching process to the second spacer. An epitaxial layer is formed in the recess.

### BACKGROUND OF THE INVENTION

1. Field of the Invention

The present invention relates generally to a semiconductor process, and more specifically, to a semiconductor process that applies dual spacers with different etching rates.

2. Description of the Prior Art

A single spacer is applied in current semiconductor processes. The spacer is formed beside a gate structure (including a gate dielectric layer, a gate electrode and a cap layer) to etch and form at least a recess in the substrate beside the spacer. An epitaxial layer is formed in the recess. Then, the spacer is removed. Other semiconductor processes may further be performed on the substrate and the gate structure.

The shape of the said epitaxial layer has a U-shaped profile structure. The U-shaped profile structure makes the spacer hard to remove entirely, which affects gate-to-drain capacitance (Cgd). Furthermore, for better performance of semiconductor structures such as MOS transistors (especially in 28 nm), height of the epitaxial layer protruding from the substrate is as high as possible, but the height of the epitaxial layer protruding from the substrate causes the spacer to remain.

Therefore, a semiconductor process, specifically a process of forming a spacer, that allows for complete removal of the spacer after an epitaxial process is performed, is needed in the industry.

### SUMMARY OF THE INVENTION

The present invention provides a semiconductor process including dual spacers with different etching rate, wherein the dual spacers would come to an L-shaped structure after being etched, so that epitaxial layers having a diamond-shaped profile structure can be formed.

The present invention provides a semiconductor process including the following steps. A substrate is provided. A gate structure is formed on the substrate. A spacer is formed on the substrate beside the gate structure, wherein the spacer comprises a first spacer and a second spacer on the external side of the first spacer. A first etching process is performed to etch and format least a recess in the substrate beside the spacer and entirely remove the second spacer, wherein the etching rate of the first etching process to the first spacer is less than the etching rate of the first etching process to the second spacer. An epitaxial layer is formed in the recess.

The present invention provides a semiconductor process applying dual spacers, that the etching rate of the inner spacer is slower than the etching rate of the outer spacer, therefore the dual spacers can be etched to an L-shaped structure in the first etching process because of different etching rate. By doing this, the epitaxial layer can have a diamond-shaped profile structure, so that the dual spacers can be entirely removed in the following process. In other words, the spacer of the present invention will not remain on the substrate or beside the gate structure, which would lead to the problem of degradation of gate-to-drain capacitance (Cgd) as the prior art.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1-6 schematically depict a cross-sectional view of a semiconductor process according to one embodiment of the present invention.

### DETAILED DESCRIPTION

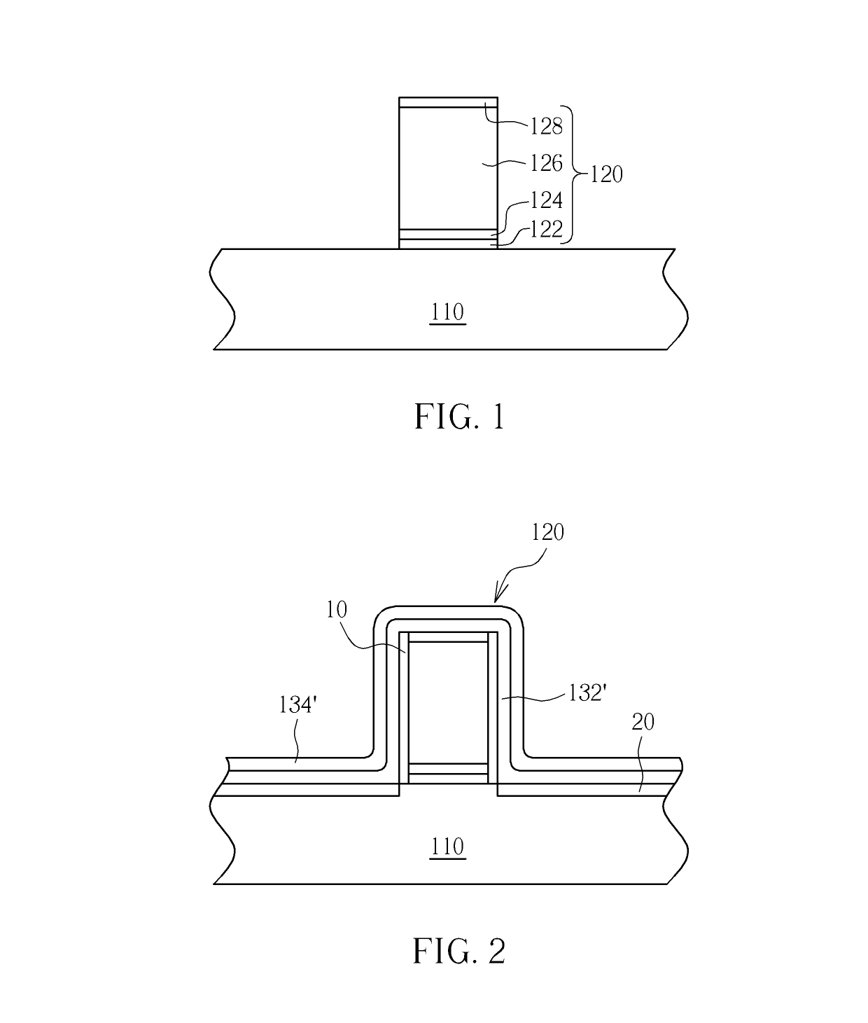

FIG. 1-6 schematically depict a cross-sectional view of a semiconductor process according to one embodiment of the present invention. As shown in FIG. 1, a substrate 110 is provided, wherein the substrate 110 includes a semiconductor substrate such as a silicon substrate, a silicon containing substrate, or a silicon-on-insulator substrate, etc. A gate structure 120 is formed on the substrate 110. In detail, forming the gate structure 120 may include: forming a buffer (not shown) layer on the substrate 110, forming a gate dielectric layer (not shown) on the buffer layer, forming a gate electrode layer (not shown) on the gate dielectric layer, and forming a cap layer (not shown) on the gate electrode layer. The cap layer, the gate electrode layer, the gate dielectric layer and the buffer layer are sequentially patterned to form a buffer layer 122, a gate dielectric layer 124, a gate electrode layer 126 and a cap layer 128. The buffer layer 122 may be an oxide layer. The gate dielectric layer 124 may be an oxide layer or a dielectric layer having a high dielectric constant. The gate electrode layer 126 may include a polysilicon layer, which may be replaced by at least a metal gate layer in following processes. The cap layer 128 may be a nitride layer. In addition, the gate structure 120 may also be formed by other processes.

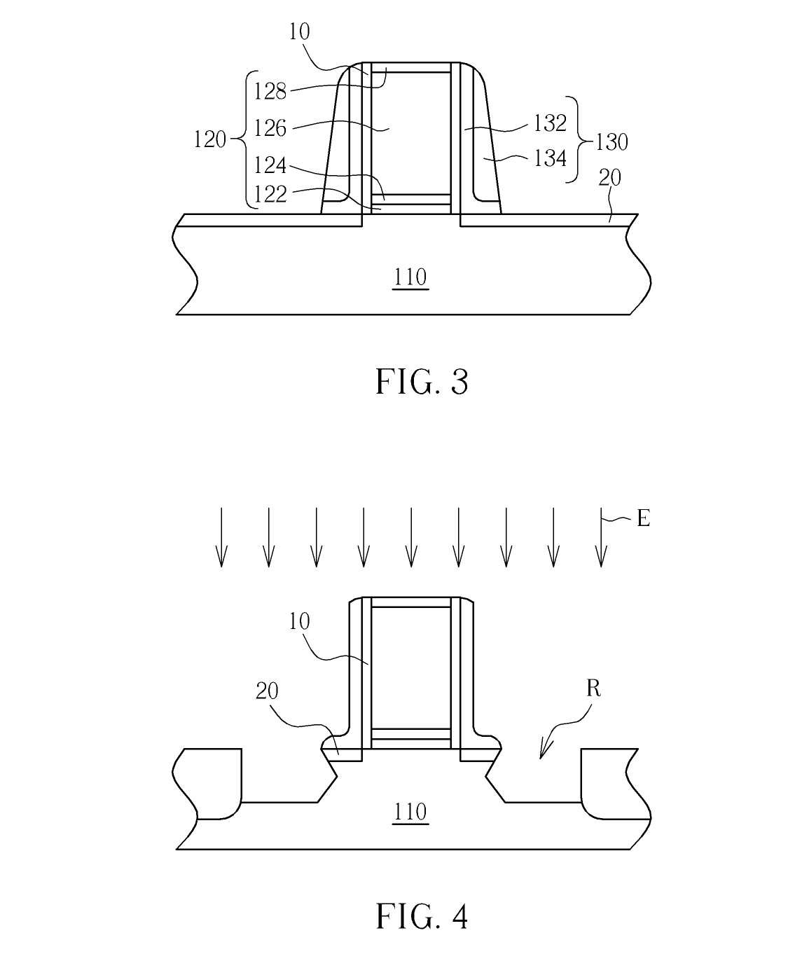

As shown in FIG. 2-3, a spacer 10 is selectively formed on the substrate 110 beside the gate structure 120; a lightly doped ion implantation process is performed to forma lightly doped source/drain region 20 in the substrate 110 beside the spacer 10. A dual spacer 130 is formed on the substrate 110 beside the spacer 10, wherein the dual spacer 130 includes a first spacer 132 and a second spacer 134 located at the external side of the first spacer 132. As shown in FIG. 2, after the lightly doped source/drain region 20 is formed, a first spacer layer 132′ and a second spacer layer 134′ are sequentially formed and cover the gate structure 120 and the substrate 110. As shown in FIG. 3, the first spacer 132 and the second spacer 134 located beside the first spacer 132 are formed on the substrate 110. In this embodiment, the first spacer 132 and the second spacer 134 are both composed of silicon nitride. The first spacer 132 and the second spacer 134 may be formed by a precursor of ammonia (NH₃). In one case, the first spacer 132 and the second spacer 134 may be formed by a precursor of silicon (Si) and ammonia (NH₃). For example, the first spacer 132 and the second spacer 134 may be formed by a precursor of hexachlorosilane (HCD), a precursor of disilane (Si₂H₆) (such as SINGEN belonging to Applied Materials, Inc.), a precursor of carbon doped hexachlorosilane (CHCD), or a precursor of hexachlorosilane deposited by an atomic layer deposition process (ALD-HCD).

As shown in FIG. 4, a first etching process E is performed to etch and form at least a recess R in the substrate 110 beside the dual spacer 130 and partially or entirely remove the second spacer 134. In this time, the dual spacer 130 is etched to become an L-shaped profile structure. In this embodiment, the second spacer 134 is entirely removed; but in another embodiment, the second spacer 134 may be partially removed. In both of these embodiments, the dual spacer 130 will be etched to become an L-shaped profile structure. The first etching process E may include a dry etching process or a wet etching process. In this embodiment, the first etching process E is a wet etching process, which uses a hydrofluoric acid or ammonia containing etchant, but it is not limited thereto. The etching rate of the first etching process E to the first spacer 132 is less than the etching rate of the first etching process E to the second spacer 134. The methods include: forming the first spacer 132 and the second spacer 134 having different structural density or hardness by forming the first spacer 132 and the second spacer 134 with different methods, so that the etching rate of the first etching process E to the first spacer 132 can be lower than the etching rate of the first etching process E to the second spacer 134. Due to the etching rate to the spacer formed by a precursor of carbide doped hexachlorosilane (CHCD) or a precursor of hexachlorosilane deposited by an atomic layer deposition process (ALD-HCD) being less than that to the spacer formed by a precursor of disilane (Si₂H₆), and the etching rate to the spacer formed by a precursor of disilane (Si₂H₆) being less than that to the spacer formed by a precursor of hexachlorosilane (HCD), different forming methods between the first spacer 132 and the second spacer 134 can be applied to form the dual spacer 130 with different etching rates. For instance, as the first spacer 132 is formed by a precursor of carbide doped hexachlorosilane (CHCD), a precursor of hexachlorosilane deposited by an atomic layer deposition process (ALD-HCD), or a precursor of disilane (Si₂H₆), the second spacer 134 can be formed by a precursor of hexachlorosilane (HCD). Or, as the first spacer 132 is formed by a precursor of carbide doped hexachlorosilane (CHCD) or a precursor of hexachlorosilane deposited by an atomic layer deposition process (ALD-HCD), the second spacer 134 can be formed by a precursor of disilane (Si₂H₆). In a preferred embodiment, as the first spacer 132 is formed by a precursor of carbide doped hexachlorosilane (CHCD), the second spacer 134 is formed by a precursor of hexachlorosilane (HCD). In another preferred embodiment, as the first spacer 132 is formed by a precursor of hexachlorosilane deposited by an atomic layer deposition process (ALD-HCD), the second spacer 134 is formed by a precursor of hexachlorosilane (HCD). The process formed by a precursor of hexachlorosilane (HCD) can be performed at different temperatures, depending upon requirements. By doing this, the etching rate of the first etching process E to the first spacer 132 can be lower than the etching rate of the first etching process E to the second spacer 134. Therefore, after the first etching process E is performed, the dual spacer 130 will have an L-shaped profile structure, as shown in FIG. 4. In this embodiment, the thickness of the first spacer 132 is thinner than the thickness of the second spacer 134. In a preferred embodiment, the ratio of the thickness of the first spacer 132 and the thickness of the second spacer 134 can be 1:4, so that the dual spacer 130 can have an L-shaped profile structure, without limited thereto. Furthermore, after the first etching process E is performed, a second etching process (not shown) may be performed to etch and form the recess R and also assist to remove the second spacer 134 completely, wherein the etchant of the second etching process uses an etchant containing a hydrofluoric acid or phosphoric acid. This avoids the second spacer 134 remaining after the first etching process E is performed, which promotes formation of an L-shaped profile structure by the dual spacer 130 after being etched to achieve the function of the present invention.

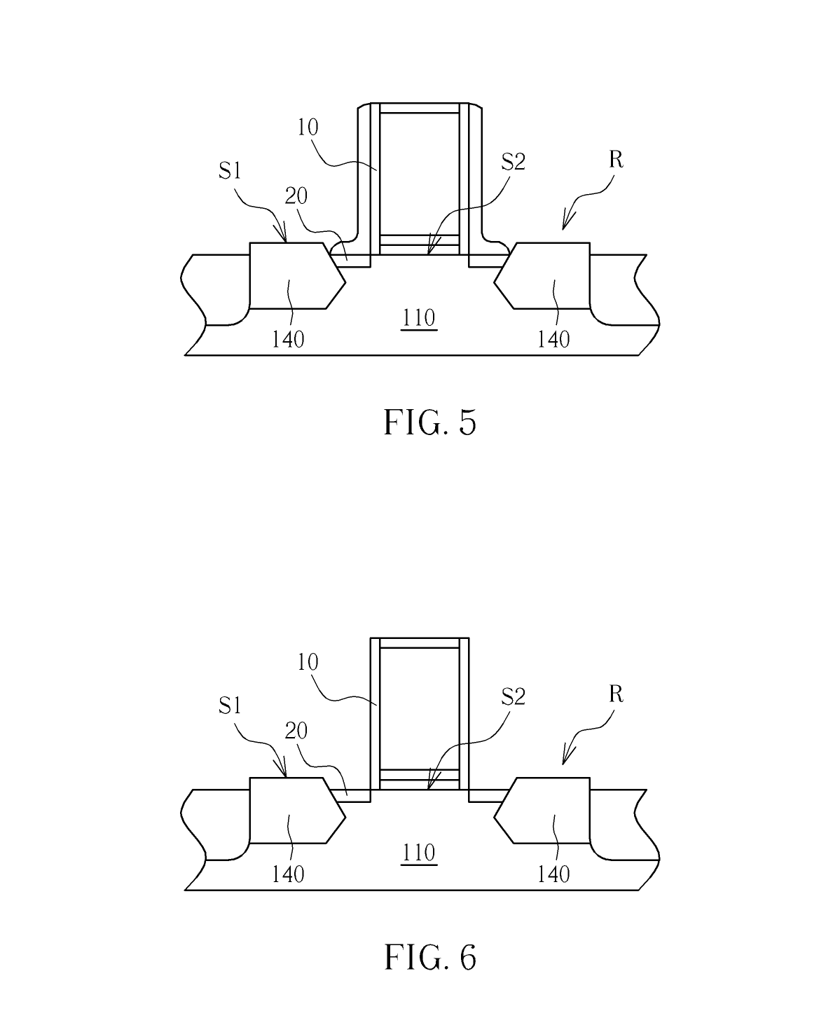

As shown in FIG. 5, an epitaxial layer 140 is formed in the recess R. The epitaxial layer 140 may include a silicon-germanium epitaxial layer or a silicon-carbide epitaxial layer, wherein the silicon-germanium epitaxial layer is suited for a PMOS transistor and the silicon-carbide epitaxial layer is suited for an NMOS transistor. In a preferred embodiment, the top surface S1 of the epitaxial layer 140 is higher than the top surface S2 of the substrate 110. As the top surface S1 of the epitaxial layer 140 is higher than the top surface S2 of the substrate 110 as possible, the performance of semiconductor structures such as MOS transistors can be improved.

As shown in FIG. 6, the dual spacer 130 is removed completely, wherein the methods of removing the dual spacer 130 may include removal by an etchant containing phosphoric acid, without limitation thereto.

It should be noted that the dual spacer 130 (including the first spacer 132 and the second spacer 134) applied in the present invention is partly etched and forms a diamond-shaped profile structure as the first etching process E etching and forming the recess R in the substrate 110 is performed, so that the epitaxial layer 140 of the present invention also has a diamond-shaped profile structure without growing along the surface of the spacer as would occur in the prior art. Thus, the dual spacer 130 can also be removed completely even if the top surface S1 of the epitaxial layer 140 is designed to be higher than the top surface S2 of the substrate 110. In other words, the present invention can solve the problem of spacer residue of the prior art.

The first spacer 132 of the present invention also has a lower etching rate than the second spacer 134 of the present invention. In general, the etching rate of the second spacer 134 may be common with the spacer of the prior art, and the etching rate of the first spacer 132 is lower than the etching rate of the second spacer 134. Therefore, the first spacer 132 is not as easy to damage as in the prior art as the first etching process E is performed, so that the poly-bump occurring in the junction between the top of the electrode layer and the spacer caused by the damage of the spacer, which exposes a part of the gate electrode layer (specifically to a polysilicon gate electrode layer) and leads to circuit leakage, can be avoided.

Above all, the present invention provides a semiconductor process applying the dual spacer, that can be formed with different hardnesses or structural densities by different processes (specifically, the etching rate of the inner spacer is less than the etching rate of the outer spacer). The dual spacer has an L-shaped profile structure after being etched during the first etching process because of different etching rates of the dual spacer. Thus, the epitaxial layer can have a diamond-shaped profile structure, so that the dual spacer can be removed completely. In other words, the spacer of the present invention does not remain on the substrate or beside the gate structure, so that the degradation of gate-to-drain capacitance (Cgd) can be avoided.

Also, due to the inner spacer of the present invention having a lower etching rate than in the prior art, it is less easily damaged by the first etching process. Thus, poly-bump protrusion from the electrode layer caused by damage to the spacer, which exposes a part of the gate electrode layer (specifically to a polysilicon gate electrode layer) and leads to circuit leakage, can be avoided.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor process, comprising:
providing a substrate;
forming a gate structure on the substrate;
forming a spacer on the substrate beside the gate structure, wherein the spacer comprises a first spacer and a second spacer on the external side of the first spacer;
performing a first etching process to etch and form at least a recess in the substrate beside the spacer and at least partially remove the second spacer, wherein the etching rate of the first etching process to the first spacer is lower than the etching rate of the first etching process to the second spacer; and
forming an epitaxial layer in the recess.

2. The semiconductor process according to claim 1, wherein the epitaxial layer comprises a silicon-germanium epitaxial layer or a silicon-carbide epitaxial layer.

3. The semiconductor process according to claim 1, wherein the top surface of the epitaxial layer is higher than the top surface of the substrate.

4. The semiconductor process according to claim 1, wherein the epitaxial layer has a diamond-shaped profile structure.

5. The semiconductor process according to claim 1, wherein the materials of the first spacer and the second spacer both contain silicon nitride.

6. The semiconductor process according to claim 5, wherein the thickness of the first spacer is thinner than the thickness of the second spacer.

7. The semiconductor process according to claim 6, wherein the ratio of the thickness of the first spacer and the thickness of the second spacer is 1:4.

8. The semiconductor process according to claim 5, wherein the first spacer is formed by a precursor of carbon doped hexachlorosilane (CHCD), a precursor of hexachlorosilane deposited by an atomic layer deposition process (ALD-HCD), or a precursor of disilane (Si₂H₆).

9. The semiconductor process according to claim 5, wherein the second spacer is formed by a precursor of hexachlorosilane (HCD) or a precursor of disilane (Si₂H₆).

10. The semiconductor process according to claim 5, wherein the first spacer is formed by a precursor of hexachlorosilane deposited by an atomic layer deposition (ALD-HCD) or a precursor of carbon doped hexachlorosilane (CHCD), and the second spacer is formed by a precursor of hexachlorosilane (HCD) or a precursor of disilane (Si₂H₆).

11. The semiconductor process according to claim 5, wherein the first spacer is formed by a precursor of carbon doped hexachlorosilane (CHCD), and the second spacer is formed by a precursor of hexachlorosilane (HCD).

12. The semiconductor process according to claim 5, wherein the first spacer is formed by a precursor of hexachlorosilane deposited by an atomic layer deposition (ALD-HCD), and the second spacer is formed by a precursor of hexachlorosilane (HCD).

13. The semiconductor process according to claim 1, wherein the spacer becomes an L-shaped profile structure by the first etching process.

14. The semiconductor process according to claim 1, wherein the first etching process comprises a wet etching process.

15. The semiconductor process according to claim 14, wherein the etchant of the wet etching process comprises a hydrofluoric acid or ammonia.

16. The semiconductor process according to claim 1, further comprising:
performing a second etching process to further remove the second spacer entirely after the first etching process is performed.

17. The semiconductor process according to claim 16, wherein the etchant of the second etching process comprises a hydrofluoric acid or phosphoric acid.

18. The semiconductor process according to claim 1, further comprising:
removing the spacer entirely after the epitaxial layer is formed.

19. The semiconductor process according to claim 18, wherein the method of removing the spacer entirely comprises removing the spacer by an etchant containing a phosphoric acid.

20. The semiconductor process according to claim 1, wherein performing the first etching process to etch and form at least a recess in the substrate beside the spacer and at least partially remove the second spacer comprises performing the first etching process to etch and form at least a recess in the substrate beside the spacer and entirely remove the second spacer.
